(19) United States
(12) Patent Application Publication
(10) Pub. No.: US 2026/0033365 A1
(43) Pub. Date: Jan. 29, 2026

(54) SEMICONDUCTOR PACKAGE SUBSTRATE

(71) Applicant: HAESUNG DS CO., LTD., Gyeongsangnam-do (KR)

(72) Inventors: Dong Jin YOON, Gyeongsangnam-do (KR); Sung Il KANG, Gyeongsangnam-do (KR)

(21) Appl. No.: 19/225,002

(22) Filed: Jun. 2, 2025

(30) Foreign Application Priority Data
Jul. 22, 2024 (KR) 10-2024-0096486

(51) Int. Cl. H01L 23/498

(52) U.S. Cl. CPC H01L 23/49838; H01L 23/49894

(57) ABSTRACT

A semiconductor package substrate includes a base substrate including a mounting area and a peripheral arca, at least one protrusion disposed between the mounting area and the peripheral area and protruding from the base substrate, and a resin inserted into a part of the base substrate and disposed around the at least one protrusion.

### CROSS-REFERENCE TO RELATED APPLICATION

This application is based on and claims priority under 35 U.S.C. § 119 to Korean Patent Application No. 10-2024-0096486, filed on Jul. 22, 2024, in the Korean Intellectual Property Office, the disclosure of which is incorporated by reference herein in its entirety.

### BACKGROUND

### 1. Field

The disclosure relates to a device, and more particularly, to a semiconductor package substrate.

### 2. Description of the Related Art

Semiconductor devices are packaged and used in semiconductor package substrates that have microcircuit patterns and/or I/O terminals. As semiconductor devices have better performance and/or become more highly integrated and electronic devices using such semiconductor devices become smaller and also have better performance, microcircuit patterns of semiconductor package substrates become narrower and more complex.

A conventional method of manufacturing a semiconductor package substrate involves forming a through-hole by using a copper clad laminate with copper foil, plating an inner surface of the through-hole to electrically connect an upper copper foil to a lower copper foil, and patterning each of the upper copper foil and the lower copper foil by using a photoresist. However, the conventional method of manufacturing a semiconductor package substrate has problems in that a manufacturing process is complicated and the precision is low.

Recently, a method of manufacturing a semiconductor package substrate by filling an insulating material into a conductive base substrate has been introduced in order to simplify a manufacturing process.

### SUMMARY

Provided is a semiconductor package substrate with improved stability.

Additional aspects will be set forth in part in the description which follows and, in part, will be apparent from the description, or may be learned by practice of the presented embodiments.

According to an aspect of the disclosure, a semiconductor package substrate includes a base substrate including a mounting area and a peripheral area, at least one protrusion disposed between the mounting area and the peripheral area and protruding from the base substrate, and a resin inserted into a part of the base substrate and disposed around the at least one protrusion.

In the present embodiment, the at least one protrusion may include a plurality of protrusions, wherein the plurality of protrusions are arranged in a serpentine shape.

In the present embodiment, the at least one protrusion may include a plurality of protrusions, wherein some of the plurality of protrusions and others of the plurality of protrusions are arranged in different columns or different rows, wherein the some of the plurality of protrusions and the others of the plurality of protrusions are misaligned with each other with respect to a first direction, which is a movement direction of the base substrate.

In the present embodiment, the at least one protrusion may include a plurality of protrusions, wherein the plurality of protrusions are connected to each other by a connecting portion.

In the present embodiment, a thickness of a portion of the base substrate may be greater than a thickness of the connecting portion.

In the present embodiment, the resin may be disposed on the connecting portion.

In the present embodiment, the connecting portion may be connected to a portion of the base substrate of the mounting area.

In the present embodiment, an edge of a planar shape of the resin disposed at a boundary of the mounting area may have an uneven shape.

In the present embodiment, the semiconductor package substrate may further include an additional protrusion disposed on an uneven portion of the edge of the planar shape of the resin protruding toward the mounting area.

In the present embodiment, a planar shape of the at least one protrusion may be a circular shape, a polygonal shape, an elliptical shape, or a lattice shape.

### BRIEF DESCRIPTION OF THE DRAWINGS

The above and other aspects, features, and advantages of certain embodiments will be more apparent from the following description taken in conjunction with the accompanying drawings, in which:

FIG. 1 is a rear view schematically illustrating a semiconductor package substrate, according to an embodiment;

FIG. 2 is a cross-sectional view schematically illustrating the semiconductor package substrate of FIG. 1;

FIG. 3 is a rear view schematically illustrating a part of the semiconductor package substrate of FIG. 1;

FIGS. 4A and 4B are cross-sectional views schematically illustrating a part of the semiconductor package substrate of FIG. 3;

FIGS. 5A to 5E are plan views illustrating a planar shape of a protrusion of FIG. 1;

FIG. 6 is a cross-sectional view schematically illustrating a semiconductor package including a semiconductor package substrate, according to an embodiment; and

FIG. 7 is a cross-sectional view schematically illustrating a part of a semiconductor package substrate, according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The disclosure will become apparent with reference to embodiments described below in detail in conjunction with the accompanying drawings. The disclosure may, however, be embodied in many different forms and should not be construed as limited to embodiments set forth herein; rather these embodiments are provided so that this disclosure will be thorough and complete, and will fully convey the scope of the disclosure to one of ordinary skill in the art, and the scope of the disclosure is defined only by the accompanying claims. The terms used herein are for the purpose of describing embodiments only and are not intended to limit the disclosure. As used herein, the singular forms “a,” “an,” and “the” are intended to include the plural forms as well, unless the context clearly indicates otherwise. It will be further understood that the terms “comprises” and/or “comprising” used herein specify the presence of stated elements, steps, operations, and/or devices, but do not preclude the presence or addition of one or more other elements, steps, operations, and/or devices. It will be understood that although the terms “first,” “second,” etc. may be used herein to describe various elements, these elements should not be limited by these terms. The terms are used only to distinguish one element from another.

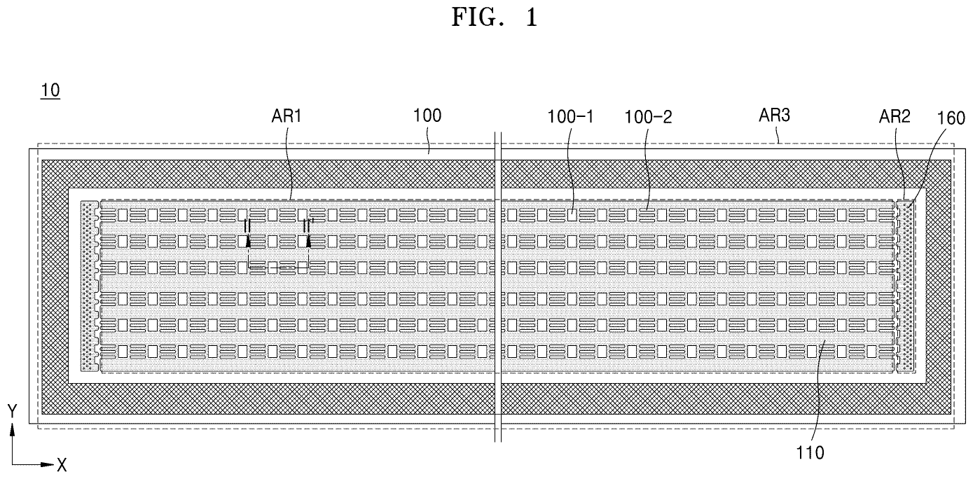

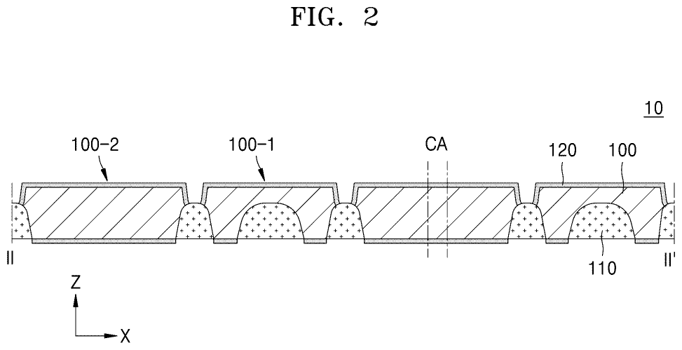

FIG. 1 is a rear view schematically illustrating a semiconductor package substrate, according to an embodiment. FIG. 2 is a cross-sectional view schematically illustrating the semiconductor package substrate of FIG. 1. In this case, FIG. 2 is a cross-sectional view taken along line II-II′ of FIG. 1.

Referring to FIGS. 1 and 2, a semiconductor package substrate 10 may include a base substrate 100, a resin 110, a plating layer 120, and a protrusion 160.

The base substrate 100 may have a flat plate shape and include an electrically conductive material. The electrically conductive material may include Fe, an Fe alloy such as Fe—Ni or Fe—Ni—Co, Cu, or a Cu alloy such as Cu—Sn, Cu—Zr, Cu—Fe, or Cu—Zn.

The base substrate 100 having a plate shape may have a top surface and a bottom surface opposite to each other. The top surface refers to a surface on which a semiconductor chip described below is to be mounted, and the bottom surface is a rear surface and refers to a surface located opposite to the top surface.

In an embodiment, a thickness of the base substrate 100 may be about 100 μm to about 500 μm, for example, about 185 μm to about 200 μm. The base substrate 100 may include at least one groove (not shown) and/or at least one through-hole (not shown). In this case, the at least one groove may be recessed from one surface of the base substrate 100, and the at least one through-hole may extend from one surface of the base substrate 100 to the other surface of the base substrate 100.

The base substrate 100 may be separated into multiple parts after a semiconductor chip (not shown) is mounted. In this case, the base substrate 100 may include a mounting area AR1 where each of a plurality of semiconductor chips is mounted. At least one mounting area AR1 may be provided. When a plurality of mounting areas AR1 are provided, the plurality of mounting areas AR1 may be spaced apart from each other. In the mounting area AR1, at least one pad unit 100-1 on which a semiconductor chip (not shown) is disposed and a lead unit 100-2 spaced apart from the pad unit 100-1 so as to be electrically insulated from the pad unit 100-1 may be disposed. In this case, when a plurality of pad units 100-1 are provided, the lead units 100-2 disposed between adjacent pad units 100-1 may be connected to each other and may be separated from each other later. A groove for separation may be formed between the lead units 100-2 adjacent to each other and connected to each other.

Also, the base substrate 100 may include a peripheral area AR3 disposed outside the mounting area AR1 and a boundary area AR2 disposed between the mounting area AR1 and the peripheral area AR3. In this case, although the boundary areas AR2 are disposed only on left and right sides of the mounting area AR1 in FIG. 1, the boundary areas AR2 may also be disposed above and below the mounting area AR1. However, for convenience of explanation, the following will be described in detail assuming that the boundary areas AR2 are disposed only on the left and right sides of the mounting area AR1.

The base substrate 100 may include a boundary groove (not shown) defining the boundary arca AR2. In this case, the boundary groove may be recessed from the top surface or the bottom surface of the base substrate 100.

The resin 110 may be disposed in at least one of the through-hole and the groove. Also, the resin 110 may be disposed inside the boundary groove. When the resin 110 is disposed in the through-hole, the resin 110 may be disposed only in a part of the through-hole. The resin 110 disposed in the groove may completely fill the inside of the groove. A material of the resin 110 is not limited as long as the resin 110 is formed of an insulating material that is not electrically conductive. For example, the resin 110 may be a thermosetting resin that is polymerized and cured by heat treatment. The resin 110 electrically insulates between wiring patterns of the semiconductor package substrate later. The filling of the resin 110 may be performed by using a liquid material, may be performed by using a solid tape including a resin component, or may be performed by using powder including a resin component.

The plating layer 120 may be disposed on at least one of the top surface and the bottom surface of the base substrate 100. For convenience of explanation, the following will be described in detail assuming that the plating layer 120 is disposed on both the top surface and the bottom surface of the base substrate 100. For example, the plating layer 120 may include at least one of a first plating layer disposed on the top surface of the base substrate 100, and a second plating layer disposed on the bottom surface of the base substrate 100. The first plating layer and the second plating layer may be respectively disposed on the top surface and the bottom surface of the base substrate 100. Each of the first plating layer and the second plating layer may be plated by using, for example, Au, Pd, or NiPd. A method such as anti-tarnish or organic film coating such as organic solderability preservative (OSP) may be used on the top surface of the base substrate 100.

The protrusion 160 may be disposed inside the boundary groove. In this case, the protrusion 160 may protrude from a bottom surface of the boundary groove. A distance from one surface (the top surface or the bottom surface) of the base substrate 100 on which the protrusion 160 is disposed to an end of the protrusion 160 may be the same as a thickness of the base substrate 100 that is not etched. The plating layer 120 may or may not be disposed at the end of the protrusion 160. For convenience of explanation, the following will be described in detail assuming that the plating layer 120 is disposed at the end of the protrusion 160.

A method of manufacturing the semiconductor package substrate 10 will now be described. First, the base substrate 100 formed of a conductive material is prepared. The base substrate 100 may have a flat plate shape including an electrically conductive material. The electrically conductive material may include Fe, an Fe alloy such as Fe—Ni or Fe—Ni—Co, Cu, or a Cu alloy such as Cu—Sn, Cu—Zr, Cu—Fe, or Cu—Zn. The base substrate 100 having a plate shape may have the top surface and the bottom surface opposite to each other.

Next, a first groove or a first trench is formed in the bottom surface of the base substrate 100. The first groove or the first trench means that the first groove or the first trench does not completely pass through the base substrate 100. A portion of the bottom surface of the base substrate 100 other than the first groove or the first trench may be a wiring pattern that extends in one direction or meanders in a plan view.

In order to form the first groove or the first trench, a dry film resist (DFR) formed of a photosensitive material is laminated on the bottom surface of the base substrate 100, and only a portion of the base substrate 100 where the first groove or the first trench is to be formed is exposed through processes such as exposure and development. Next, a portion of the bottom surface of the base substrate 100 not covered by the DFR may be etched by using an etching solution such as copper chloride or iron chloride, to form the first groove or the first trench formed in the bottom surface without passing through the base substrate 100.

A portion remaining on the bottom surface of the base substrate 100 that is not removed, that is, a portion other than the first groove or the first trench, may function as a wiring pattern later. Accordingly, when the first groove or the first trench is formed in the bottom surface of the base substrate 100, a width of a portion between adjacent grooves or trenches may be preferably about 20 μm to about 30 μm, which is a width of a typical wiring pattern.

When the first groove or the first trench is formed in the bottom surface of the base substrate 100, a depth of the first groove or the first trench may be preferably about 80% to about 90% of a thickness of the base substrate 100. For example, a remaining thickness of a portion where the first groove or the first trench of the base substrate 100 is formed may be about 10 μm to about 40 μm.

When a depth of the first groove or the first trench is greater than this, handling of the base substrate 100 or the semiconductor package substrate may not be easy during a semiconductor package substrate manufacturing process or a subsequent packaging process. Also, when a depth of the first groove or the first trench is greater than this, in some cases, a through-hole passing through the bottom surface and the top surface of the base substrate 100 may be formed due to a tolerance or the like when forming the first groove or the first trench. When a depth of the first groove or the first trench is less than this, a subsequent process may not be easy when manufacturing the semiconductor package substrate or the semiconductor package substrate finally manufactured may be excessively thin.

When the first groove or the first trench is formed, a separate boundary groove may also be formed in the base substrate 100. In this case, a thickness of the base substrate 100 where the boundary groove is disposed may be greater than or equal to ½ of a thickness of the base substrate 100 that is not etched. A thickness of a portion of the base substrate 100 where the boundary groove is disposed may be greater than a thickness of a portion of the base substrate 100 where the first groove or the first trench is disposed. When a thickness of the base substrate 100 where the boundary groove is disposed is less than ½ of a thickness of the base substrate 100 that is not etched, the base substrate 100 may be too thin, and thus, a portion of the base substrate 100 where the boundary groove is disposed may be broken or removed, thereby causing a defect in the semiconductor package substrate 10.

When the boundary groove is formed, the protrusion 160 may be formed at the same time. In this case, the DFR may be disposed on a top surface of the protrusion 160 to maintain a shape without etching when the first groove, the first trench and the boundary groove are formed.

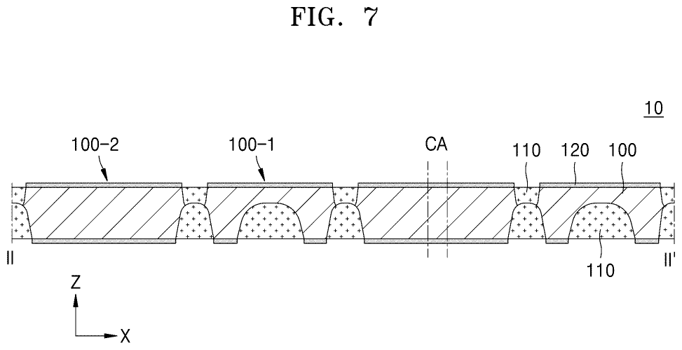

Next, the first groove or the first trench of the base substrate 100 is filled with the resin 110. In this case, the resin 110 may also be disposed inside the boundary groove. When the resin 110 is filled, as shown in FIG. 7, the resin 110 may not only fill the first groove or the first trench of the base substrate 100, but may also cover at least a part of the bottom surface of the base substrate 100. When the resin 110 is over-applied in this case, the over-applied resin 110 may be removed by using mechanical processing such as brushing, grinding, or polishing or may be removed by using chemical resin etching so that the resin 110 is located only in the first groove or the first trench of the base substrate 100.

When the resin 110 is filled, it may be considered to fill only the first groove or the first trench of the base substrate 100. In this case, the resin 110 may also be disposed inside the boundary groove. However, in this case, there is a problem that the first groove or the first trench of the base substrate 100 may not be appropriately filled with the resin 110.

Next, the top surface of the base substrate 100 is etched to form a portion where the resin 110 filling the first groove or the first trench is exposed. The top surface of the base substrate 100 may be etched in various ways. For example, a DFR formed of a photosensitive material is laminated on the top surface of the base substrate 100, and only a portion of the top surface of the base substrate 100 to be etched is exposed through processes such as exposure and development. Next, a portion of the top surface of the base substrate 100 not covered by the DFR may be etched by using an etching solution such as copper chloride or iron chloride to expose at least a part of the resin 110 on the top surface of the base substrate 100.

In the above case, the boundary groove may also be formed in the top surface of the base substrate 100. A method of forming the boundary groove is the same as or similar to a method of forming the first groove or the first trench described above. The protrusion 160 may be disposed inside the boundary groove. In this case, the resin 110 may be disposed inside the boundary groove through a separate process. In this case, the boundary groove may not be formed in the bottom surface of the base substrate 100. That is, the boundary groove may be formed only in one of the top surface and the bottom surface of the base substrate 100.

According to the above process, a wiring pattern between the resins 110 is formed even on the bottom surface of the base substrate 100, and a wiring pattern between the resins 110 is formed even on the top surface of the base substrate 100. In the case of the semiconductor package substrate, the wiring pattern on the top surface and the wiring pattern on the bottom surface are electrically connected, and thus, conductive layer patterning of the top surface and conductive layer patterning of the bottom surface should be performed in a preset manner.

Next, the plating layer 120 may be formed on at least a part of the remaining portion of the base substrate 100. When necessary, the plating layer 120 may be formed on the top surface, the bottom surface, and an inner surface of the first groove or the first trench of the base substrate 100 excluding the resin 110. The plating layer 120 may be plated by using, for example, Au, Pd, or NiPd Au-Alloy. A method such as anti-tarnish or organic film coating such as organic solderability preservative (OSP) may be used on the top surface of the base substrate 100.

Before the resin 110 is filled in the first groove, the first trench, or the boundary groove of the base substrate 100, an inner surface of the first groove, the first trench, or the boundary groove may be roughened. Accordingly, an adhesive force between the resin 110 and the base substrate 100 may be dramatically increased. Plasma treatment, ultraviolet treatment, or a hydrogen peroxide sulfuric acid-based solution may be used to roughen the inner surface of the first groove, the first trench, or the boundary groove of the base substrate 100, and in this case, a roughness of the inner surface of the first groove, the first trench, or the boundary groove of the base substrate 100 may be 150 nm or more.

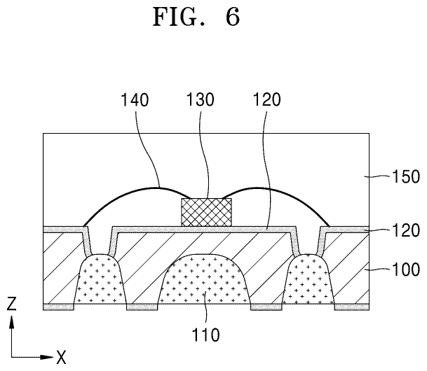

The semiconductor package substrate 10 manufactured as described above may be separated from each other by cutting a cutting area CA. For example, a portion between the mounting areas AR1, between leads disposed in the mounting area AR1, and between the mounting area AR1 and the peripheral area AR3 may be cut. Also, the mounting area AR1 may be cut into a plurality of parts. The semiconductor package substrate 10 may be cut after the manufacture of the semiconductor package substrate 10 is completed, or may be cut after a semiconductor chip 130 is mounted on the semiconductor package substrate 10. In another embodiment, as shown in FIG. 6, the semiconductor chip 130 may be mounted on the semiconductor package substrate 10, a wire 140 may be formed, a molding layer 150 may be formed, and then the molding layer 150 and the semiconductor package substrate 10 may be cut.

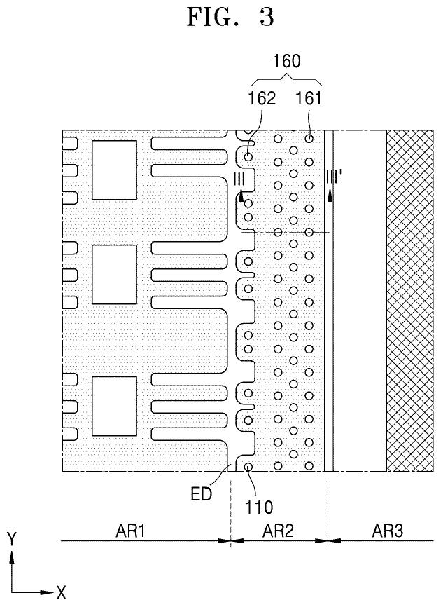

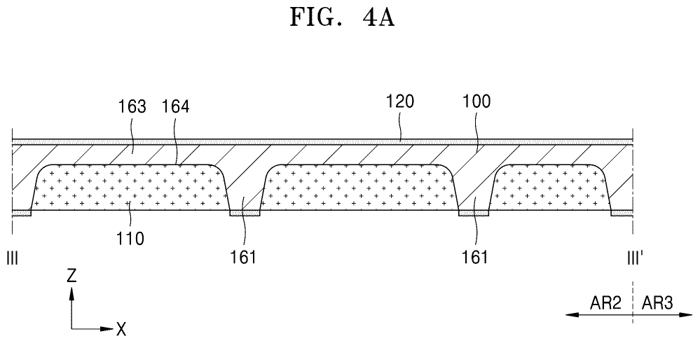

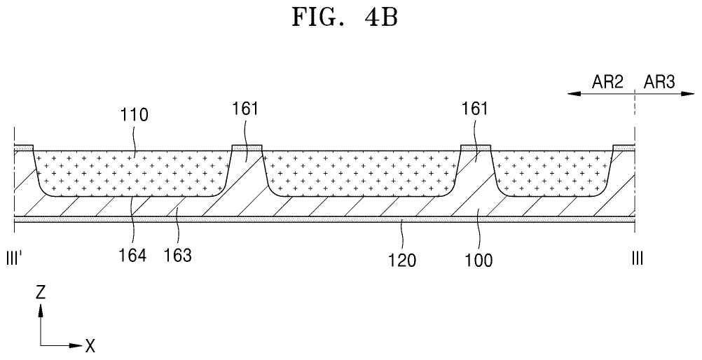

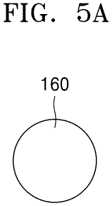

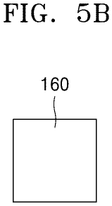

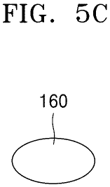

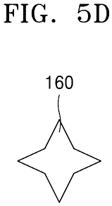

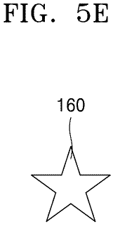

FIG. 3 is a rear view schematically illustrating a part of the semiconductor package substrate of FIG. 1. FIGS. 4A and 4B are cross-sectional view schematically illustrating a part of the semiconductor package substrate of FIG. 3. FIGS. 5A to 5E are plan views illustrating a planar shape of a protrusion of FIG. 1. FIG. 4A illustrates a case where the protrusion is disposed on the bottom surface of the base substrate. FIG. 4B illustrates a case where the protrusion is disposed on the top surface of the base substrate. In this case, FIGS. 4A and 4B are cross-sectional views taken along line III-III′ of FIG. 3.

Referring to FIG. 3, the boundary area AR2 may be disposed between the peripheral arca AR3 and the mounting arca AR1. Although not shown, when a plurality of mounting areas AR1 are provided, the boundary area AR2 may be disposed between the plurality of mounting areas AR1. In this case, one of edges of the boundary area AR2 may be an outermost boundary of leads disposed at an outermost portion of the mounting area AR1. In this case, the leads disposed at the outermost portion of the mounting area AR1 may be connected to each other to form a part of an edge ED of the boundary area AR2.

A planar shape of the part of the edge ED of the boundary area AR2 may include an uneven shape. That is, a part of the edge ED of the boundary area AR2 adjacent to the mounting area AR1 may include a portion protruding toward the mounting area AR1 and a portion recessed away from the mounting area AR1. Accordingly, when the resin 110 is disposed inside a boundary groove 164, a contact area between an inner surface of the boundary groove 164 and the resin 110 may increase, thereby increasing a coupling force between the inner surface of the boundary groove 164 and the resin 110.

In the above case, the boundary area AR2 may include the boundary groove 164 formed to correspond to the edge of the boundary area AR2. In this case, the edge of the boundary arca AR2 may correspond to an edge of the boundary groove 164 formed in the bottom surface of the base substrate 100.

The protrusion 160 may be disposed inside the boundary groove 164. In this case, the protrusion 160 may include a plurality of first protrusions 161 arranged in at least one column, and a second protrusion 162 (or additional protrusion) disposed on the edge ED of the boundary area AR2.

The plurality of first protrusions 161 may be provided. The plurality of first protrusions 161 may be arranged in a direction perpendicular to a movement direction of the base substrate 100. The plurality of first protrusions 161 may be arranged in a zigzag or serpentine shape. In this case, some of the plurality of first protrusions 161 may be arranged in a first column, and others of the plurality of first protrusions 161 may be arranged in a second column different from the first column. In this case, the first protrusion 161 arranged in the first column may be disposed between adjacent first protrusions 161 from among the first protrusions 161 arranged in the second column. That is, in the movement direction of the base substrate 100, the first protrusion 161 arranged in the first column may be disposed between the first protrusions 161 arranged in the second column and adjacent to each other, and the first protrusion 161 arranged in the second column may be disposed between the first protrusions 161 arranged in the first column and adjacent to each other. Others of the plurality of first protrusions 161 may be aligned in a third column. In this case, the first protrusion 161 arranged in the third column may be disposed at the same position as the first protrusion 161 arranged in the first column. In the above case, when the plurality of first protrusions 161 are arranged in a plurality of columns to be spaced apart from each other, the protrusions 161 arranged in even-numbered columns have the same arrangement and the first protrusions 161 arranged in odd-numbered columns have the same arrangement. Also, the first protrusions 161 arranged in the even-numbered columns and the first protrusions 161 arranged in the odd-numbered columns may be arranged so as not to overlap each other in the movement direction of the base substrate 100.

The plurality of first protrusions 161 may be connected to each other through the base substrate 100. In this case, the base substrate 100 may include a connecting portion 163 that connects the first protrusions 161 to each other and forms the bottom surface of the boundary groove 164. That is, as shown in FIG. 4A, when the boundary groove 164 is disposed in the bottom surface of the base substrate 100, the plurality of first protrusions 161 may be connected to portions of the top surface of the base substrate 100. In this case, the connecting portion 163 may be integrally formed with the top surface of the base substrate 100 and may be connected to the top surface of the base substrate 100. Also, as shown in FIG. 4B, when the boundary groove 164 is disposed in the top surface of the base substrate 100, the plurality of first protrusions 161 may be connected to portions of the bottom surface of the base substrate 100. In this case, the connecting portion 163 may be integrally formed with the bottom surface of the base substrate 100 and may be connected to the bottom surface of the base substrate 100. The connecting portion 163 may connect the plurality of first protrusions 161 to each other, and may be connected to the plurality of first protrusions 161 and to the base substrate 100 of the mounting area AR1 and the base substrate 100 of the peripheral area AR3. In this case, the boundary groove 164 may be defined by a side surface of the base substrate 100 of the mounting area AR1, a side surface of the base substrate 100 of the peripheral area AR3, and one surface of the connecting portion 163.

The second protrusion 162 may be disposed on the portion of the part of the edge ED of the boundary area AR2 adjacent to the mounting area AR1 and protruding toward the mounting area AR1. In this case, the second protrusion 162 may be formed in a manner that is the same as or similar to that of the first protrusion 161. That is, the second protrusion 162 may be connected to the base substrate 100 and may protrude from the bottom surface of the boundary groove 164.

In the above case, the resin 110 may be disposed inside the boundary groove 164. Because the resin 110 fills the inside of the boundary groove 164, when the semiconductor package substrate is bent around the boundary groove 164, warpage of the semiconductor package substrate 10 of the boundary area AR2 may be accepted to some extent. Also, accordingly, a situation where an excessive force is applied to the base substrate 100 adjacent to the boundary area AR2 to cause cracks in the base substrate 100 or breakage of the base substrate 100 may be prevented. In particular, when the base substrate 100 is transferred, the base substrate 100 may bend and stretch due to a force applied to the base substrate 100. In this case, the base substrate 100 may be damaged at a boundary portion of the mounting area AR1. The boundary area AR2 is disposed at the boundary portion of the mounting area AR1 to accept warpage of the base substrate 100 to some extent.

A planar shape (rear shape) of the protrusion 160 may be any of various shapes. For example, a planar shape (rear shape) of the protrusion 160 may be a circular shape as shown in FIG. 5A. In another embodiment, a planar shape (rear shape) of the protrusion 160 may be a quadrangular shape as shown in FIG. 5B. In this case, a planar shape (rear shape) of the protrusion 160 is not limited thereto, and may be any of a polygonal shapes including a triangular shape and a square shape. In another embodiment, a planar shape (rear shape) of the protrusion 160 may be an elliptical shape as shown in FIG. 5C. In another embodiment, a planar shape (rear shape) of the protrusion 160 may be a star shape as shown in FIGS. 5D and 5E. In this case, a planar shape of the protrusion 160 is not limited thereto, and although not shown, a planar shape (rear shape) of the protrusion 160 may be an irregular shape other than a circular shape, an elliptical shape, and a polygonal shape. The irregular shape may refer to a shape that is inconsistent, such as a cross shape or a star shape.

Planar shapes (rear shapes) of the plurality of protrusions 160 may be island shapes. That is, ends of the plurality of protrusions 160 may be exposed from the resin 110, and the ends of the plurality of protrusions 160 exposed from the resin 110 may not be connected to each other.

The plurality of protrusions 160 may have a plurality of pillar shapes connected to the base substrate 100 and spaced apart from each other. The plurality of protrusions 160 may provide a space in which the resin 110 is disposed, and may not only increase a coupling force between the resin 110 and the base substrate 100 but also ensure some rigidity of the boundary area AR2 through the protrusions 160.

FIG. 6 is a cross-sectional view schematically illustrating a semiconductor package including a semiconductor package substrate, according to an embodiment.

Referring to FIG. 6, the semiconductor chip 130 is mounted on the base substrate 100 and the plating layer 120 of the semiconductor package substrate. In this case, the resin 110 may be inserted into a part of the base substrate 100. The semiconductor chip 130 may be mounted on a flat portion of a top surface of the semiconductor package substrate, and the semiconductor chip 130 may be electrically and physically connected to a lead of the base substrate 100 by the wire 140. The wire 140 may be connected to the semiconductor chip 130 and the lead by using wire bonding. One side of the wire 140 is attached to the lead, and the other side of the wire 140 is connected to the semiconductor chip 130.

The molding layer 150 may be formed on the semiconductor chip 130 mounted on the semiconductor package substrate. The molding layer 150 may seal the semiconductor chip 130 from the outside, and the molding layer 150 may be formed in a single molding structure, a double molding structure, or a triple or more molding structure. The molding layer 150 may be formed by curing the resin 110, and may include at least one of, for example, a fluorescent material and a light diffusing material. When necessary, a light-transmitting material that does not include a fluorescent material or a light diffusing material may be used.

FIG. 7 is a cross-sectional view schematically illustrating a part of a semiconductor package substrate, according to another embodiment.

Referring to FIG. 7, the semiconductor package substrate 10 may include the base substrate 100, the resin 110, the plating layer 120, and a protrusion (not shown). In this case, the base substrate 100, the plating layer 120, and the protrusion are the same as or similar to those described with reference to FIGS. 1 to 3, and thus, a detailed description thereof will be omitted.

The resin 110 may be disposed in at least one of the through-hole and the groove. In this case, the resin 110 may fill the entire through-hole. In this case, the resin 110 may be formed simultaneously or sequentially on the bottom surface and the top surface of the base substrate 100 as described above. In this case, a method of disposing the resin 110 in the through-hole is the same as or similar to that described above, and thus, a detailed description thereof will be omitted.

Accordingly, because the resin 110 completely fills the inside of the through-hole, flexibility of the semiconductor package substrate 10 may be provided and insulation between the base substrates 100 spaced apart from each other may be effectively provided.

According to embodiments, warpage of a semiconductor package substrate may be reduced. According to embodiments, a defect rate of the semiconductor package substrate may be reduced. According to embodiments, damage to a base substrate at an outer portion of a mounting area of the semiconductor package substrate may be reduced.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope of the disclosure as defined by the following claims.

What is claimed is:

1. A semiconductor package substrate comprising:
a base substrate comprising a mounting area and a peripheral area;
at least one protrusion disposed between the mounting area and the peripheral area and protruding from the base substrate; and
a resin inserted into a part of the base substrate and disposed around the at least one protrusion.

2. The semiconductor package substrate of claim 1, wherein the at least one protrusion comprises a plurality of protrusions,
wherein the plurality of protrusions are arranged in a serpentine shape.

3. The semiconductor package substrate of claim 1, wherein the at least one protrusion comprises a plurality of protrusions,
wherein some of the plurality of protrusions and others of the plurality of protrusions are arranged in different columns or different rows,
wherein the some of the plurality of protrusions and the others of the plurality of protrusions are misaligned with each other with respect to a first direction, which is a movement direction of the base substrate.

4. The semiconductor package substrate of claim 1, wherein the at least one protrusion comprises a plurality of protrusions,
wherein the plurality of protrusions are connected to each other by a connecting portion.

5. The semiconductor package substrate of claim 4, wherein a thickness of a portion of the base substrate is greater than a thickness of the connecting portion.

6. The semiconductor package substrate of claim 4, wherein the resin is disposed on the connecting portion.

7. The semiconductor package substrate of claim 4, wherein the connecting portion is connected to a portion of the base substrate of the mounting area.

8. The semiconductor package substrate of claim 7, wherein an edge of a planar shape of the resin disposed at a boundary of the mounting area has an uneven shape.

9. The semiconductor package substrate of claim 8, further comprising an additional protrusion disposed on an uneven portion of the edge of the planar shape of the resin protruding toward the mounting area.

10. The semiconductor package substrate of claim 1, wherein a planar shape of the at least one protrusion is a circular shape, a polygonal shape, an elliptical shape, or a lattice shape.
